(19) United States
(12) Patent Application Publication
(10) Pub. No.: US 2010/0307579 A1
(43) Pub. Date: Dec. 9, 2010

(54) Pseudo-Periodic Structure for Use in Thin Film Solar Cells

(75) Inventors: Xing Sheng, Cambridge, MA (US); Jifeng Liu, Cambridge, MA (US); Jurgen Michel, Arlington, MA (US); Anuradha M. Agarwal, Weston, MA (US); Lionel C. Kimerling, Concord, MA (US)

Correspondence Address: Sunstein Kann Murphy & Timbers LLP, 125 SUMMER STREET, BOSTON, MA, 02110-1618, US

(73) Assignee: MASSACHUSETTS INSTITUTE OF TECHNOLOGY, Cambridge, MA (US)

(21) Appl. No.: 12/730,665

(22) Filed: Mar. 24, 2010

Related U.S. Application Data
(60) Provisional application No. 61/183,727, filed on Jun. 3, 2009.

(51) Int. Cl. H01L 31/0232; H01L 31/18

(52) U.S. Cl. 136/256; 438/69; 257/E31.127

(57) ABSTRACT

A method of manufacturing a photovoltaic cell includes providing an active absorption layer, forming a pseudo-periodic grating adjacent to the active absorption layer, and forming a reflector adjacent to the pseudo-periodic grating. A photovoltaic cell includes an active absorption layer, a pseudo-periodic grating adjacent to the active absorption layer, and a reflector adjacent to the pseudo-periodic grating.

### CROSS-REFERENCE TO RELATED APPLICATIONS

This patent application claims priority to U.S. Provisional Patent Application No. 61/183,727 filed Jun. 3, 2009, entitled LOW COST SELF-ASSEMBLED DETERMINISTIC PSEUDO-PERIODIC STRUCTURE FOR LIGHT TRAPPING IN THIN FILM SOLAR CELLS, the disclosure of which is incorporated by reference herein in its entirety.

### FIELD OF THE INVENTION

The invention generally relates to thin film solar cells and, more particularly, the invention relates to a structure for use in thin film solar cells.

### BACKGROUND OF THE INVENTION

Nowadays, energy shortage and environment disruption like global warming have become worldwide issues due to the consumption of fossil fuel. Among techniques that utilize new energy sources, the solar cell is considered to be very promising and has already achieved wide application for space and terrestrial power supply. However, most solar cells are based on silicon wafers. The cost of this technique, which is dominated by the starting material, is difficult to be reduced.

Thin film silicon solar cells based on inexpensive substrates are designed to reduce the silicon consumption by 100 fold so that the materials cost becomes negligible. However, as the film becomes thinner, the absorption of photons with long wavelengths gets weaker. This problem is severe especially for silicon because of its indirect bandgap, thus the power conversion efficiency is decreased. To overcome this limit, many different light trapping schemes have been proposed to increase the optical path length in thin film silicon. For example, metals are deposited on the backside to reflect light back into the absorptive layer. Another example is to utilize chemicals or plasma to etch the front or back side of solar cells, generating rough thereby antireflective or scattering surfaces. However, most of these methods have their own limitations. For some of them, the parameters that effect the formation of the structures (e.g., surface roughness, height of the texturing, periodicity of the texturing) are difficult to control, making it impossible to optimize light trapping structures, while for others the fabrication methods are too expensive to be scaled to large area applications.

### SUMMARY OF THE INVENTION

In accordance with one embodiment of the invention, a method of manufacturing a photovoltaic cell includes providing an active absorption layer, forming a pseudo-periodic grating adjacent to the active absorption layer, and forming a reflector adjacent to the pseudo-periodic grating. In related embodiments, the reflector may be a distributed Bragg reflector. Forming the pseudo-periodic grating may include forming an aluminum layer adjacent to the absorption layer, and anodizing the aluminum layer in the presence of an acid to establish a pseudo-periodic structure of aluminum oxide. Forming the pseudo-periodic grating may further include forming a grating layer adjacent to the pseudo-periodic structure and then removing the pseudo-periodic structure, so that the grating layer forms the pseudo-periodic grating. The grating layer may be made of silicon, a transparent conductive oxide material and/or materials with high refractive indices. Forming the pseudo-periodic grating may further include removing at least some portion of the active absorption layer in pore areas of the pseudo-periodic structure and then removing the pseudo-periodic structure so that a region of the active absorption layer forms the pseudo-periodic grating. Embodiments may include a device having a photovoltaic cell produced according to the method.

In accordance with another embodiment of the invention, a photovoltaic cell includes an active absorption layer, a pseudo-periodic grating adjacent to the active absorption layer, and a reflector adjacent to the pseudo-periodic grating. In related embodiments, the reflector may be a distributed Bragg reflector. The pseudo-periodic grating may be made of silicon, aluminum oxide, such as porous aluminum oxide, a transparent conductive oxide material and/or materials with high refractive indices.

In accordance with another embodiment of the invention, a method of manufacturing a photovoltaic cell includes providing an active absorption layer, forming an aluminum layer adjacent to the absorption layer, anodizing the aluminum layer in the presence of an acid to form a porous aluminum oxide layer, and forming a reflector adjacent to the porous aluminum oxide layer. In related embodiments, the reflector may be a distributed Bragg reflector. The method may further include forming a grating layer adjacent to the porous aluminum oxide layer and then removing the porous aluminum oxide layer. The grating layer may be made of a transparent conductive oxide material, silicon, and/or materials with high refractive indices. The method may further include removing at least some portion of the active absorption layer in pore areas of the porous aluminum oxide layer and then removing the porous aluminum oxide layer. Embodiments may include a device having a photovoltaic cell produced according to the method.

### BRIEF DESCRIPTION OF THE DRAWINGS

The foregoing features of various embodiments of the invention will be more readily understood by reference to the following detailed description, taken with reference to the accompanying drawings, in which:

FIG. 1 shows a process of producing a pseudo-periodic grating according to embodiments of the present invention;

FIG. 2 shows an idealized sketch of a porous aluminum oxide film structure;

FIG. 3 shows a scanning electron micrograph of a porous aluminum oxide layer produced according to embodiments of the present invention;

FIG. 4 is a graph showing the porous aluminum oxide layer thickness versus the anodization time for films made according to embodiments of the present invention;

FIGS. 5a-5c show scanning electron micrographs of the porous aluminum oxide layer thickness for various anodization times;

FIG. 6 is a graph showing the porous spacing versus the DC voltage for films made according to embodiments of the present invention;

FIGS. 7a-7c show scanning electron micrographs of the porous aluminum oxide layer pore spacing for various DC voltages;

FIG. 8 is a graph showing the porous aluminum oxide layer pore diameter versus the pore widening time for films made according to embodiments of the present invention;

FIGS. 9a-9c show scanning electron micrographs of the porous aluminum oxide layer pore diameter for various pore widening times;

FIG. 10 shows a scanning electron micrograph of a porous aluminum oxide structure formed according to embodiments of the present invention and a 2D fast Fourier transformation of the micrograph;

FIGS. 11a-11c schematically show a process of manufacturing a photovoltaic cell according to embodiments of the present invention and FIG. 11d shows its light trapping effect;

FIG. 12 schematically shows an exemplary photovoltaic cell according to embodiments of the present invention; and

FIGS. 13a-13c show a process of manufacturing a photovoltaic cell using the porous aluminum oxide layer as a sacrificial masking layer according to embodiments of the present invention.

### DESCRIPTION OF ILLUSTRATIVE EMBODIMENTS

Definitions. As used in this description and the accompanying claims, the following terms shall have the meanings indicated, unless the context otherwise requires:

A “pseudo-periodic” structure is a structure having irregularity in at least one of opening size and spacing between openings, while the openings nevertheless have a controllable and characterizable size distribution and a median size. A grating having a pseudo-periodic structure is herein called a “pseudo-periodic grating”. A method of forming a pseudo-periodic grating includes forming a porous aluminum oxide layer, the pores of which correspond to openings in the grating.

Various embodiments of the present invention provide a pseudo-periodic structure, and method of producing same, that may be used as a pseudo-periodic grating in a photovoltaic cell or may be used as a sacrificial patterning layer in forming the pseudo-periodic grating in a photovoltaic cell. The photovoltaic cell may include an active absorption layer, a pseudo-periodic grating formed adjacent to or in the active absorption layer, and a reflector, preferably a distributed Bragg reflector, formed adjacent to the pseudo-periodic grating. Other layers may also be used in addition to the active absorption layer, the pseudo-periodic grating, and the reflector on or between these various layers as known by those skilled in the art. The pseudo-periodic grating may be used within the photovoltaic cell to diffract the light into oblique angles. Unlike periodic gratings, the pseudo-periodic grating structure has a controlled randomness to further enhance the light trapping effect.

The pseudo-periodic grating may be fabricated by various methods, such as aluminum anodization or block copolymerization, and thus avoids expensive lithography steps and may be easily scaled to large areas. Embodiments of the present invention are capable of controlling and optimizing the pseudo-periodic grating structure, such as thickness, periodicity, and degree of randomness. Advantages include a significantly reduced cost of making the pseudo-periodic grating structure while further enhancing the performance of photovoltaic cells that may use such a structure. Details of illustrative embodiments are discussed below.

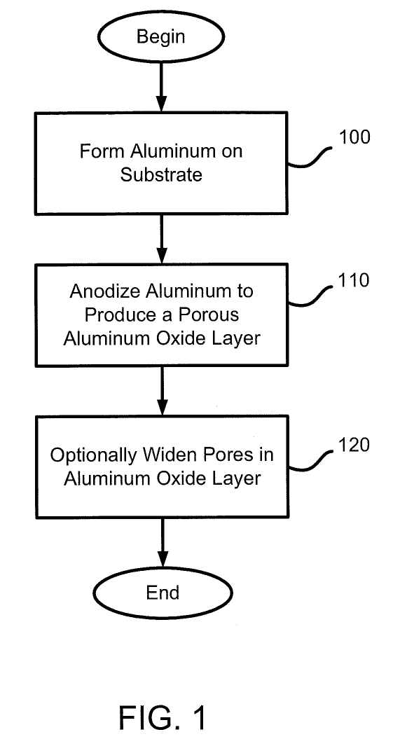

FIG. 1 shows a method of forming a pseudo-periodic grating according to embodiments of the present invention. In step 100, an aluminum layer is formed adjacent to a substrate. The aluminum layer may be formed by any known method, such as physical vapor deposition (e.g., e-beam evaporation), electroplating, and chemical vapor deposition. The aluminum layer formed may be any desired thickness depending on the desired thickness of the subsequently formed aluminum oxide layer as described in more detail below. For example, the aluminum layer may be greater than 0 to about 1000 nm or greater, preferably about 200 nm. The substrate preferably includes an active absorption layer that may be used in a photovoltaic cell. The active layer may be p-n, p-i-n or multi-junction made of semiconductors, e.g., crystalline silicon or amorphous silicon, which is capable of converting sunlight into electrical energy. The active layer may have a thickness of about 0.1-50 μm, which allows only a part of the light to be absorbed before reaching the pseudo-periodic grating formed on its other side, although other thicknesses may be used.

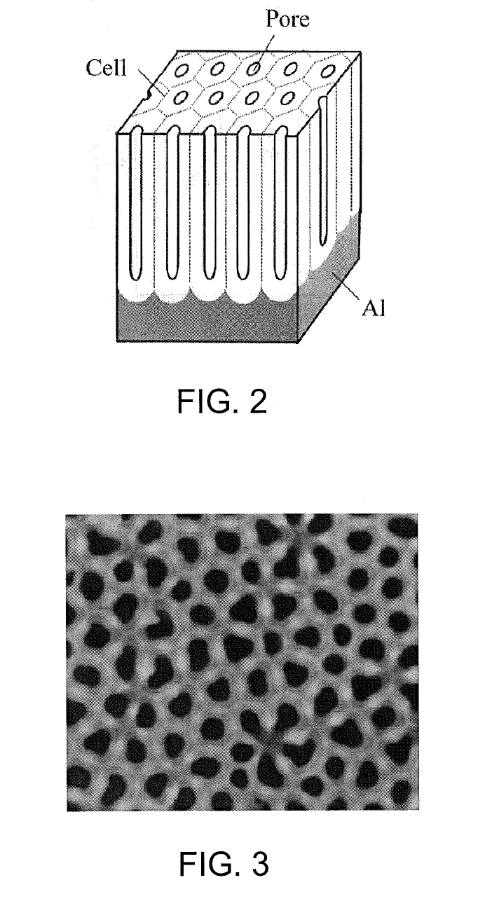

In step 110, the aluminum layer is anodized in an acidic electrolyte to produce a porous aluminum oxide layer. As known by those skilled in the art, the aluminum anodization process involves placing the aluminum film in an appropriate electrolyte and applying a voltage so that the aluminum layer is oxidized leaving an aluminum oxide film on the substrate. Depending on the anodization parameters, a predominantly porous aluminum oxide film or a barrier layer aluminum oxide film, which is not porous, may be produced. In embodiments of the present invention, a porous aluminum oxide film is formed adjacent to the substrate. FIG. 2 shows an idealized sketch of a porous aluminum oxide film having a hexagonal cell structure with each cell having a cell wall and a pore located at the center of each cell. As shown, even when a porous aluminum oxide layer is formed, a barrier oxide layer is formed at the bottom of the porous aluminum oxide layer adjacent to the aluminum layer or substrate during the anodization process. Actual films of porous aluminum oxide are typically produced with more disorder than this idealized structure with a distribution of pore diameters and cell size and spacing from one another. For example, FIG. 3 shows a scanning electron micrograph of a porous aluminum oxide layer produced according to embodiments of the present invention.

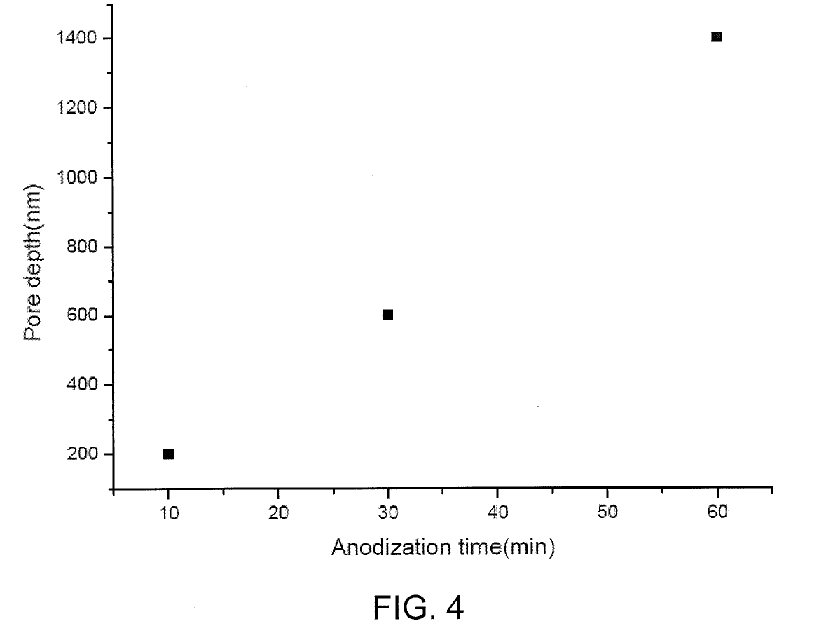

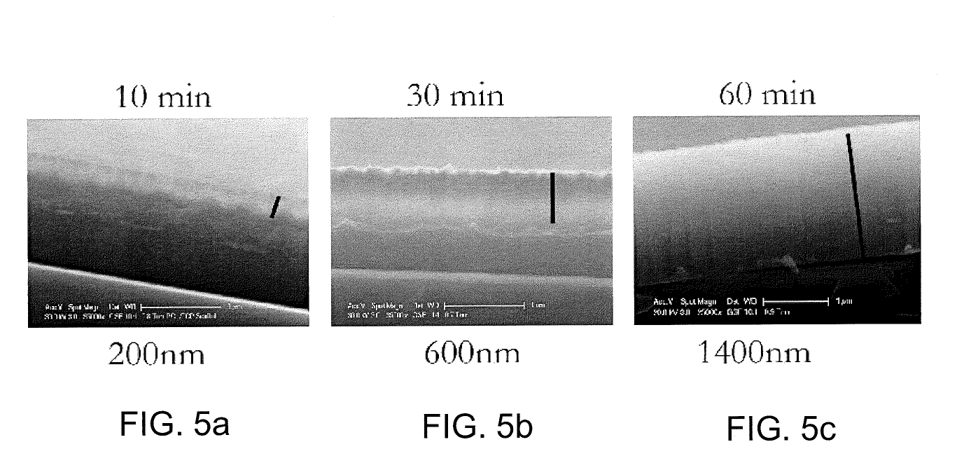

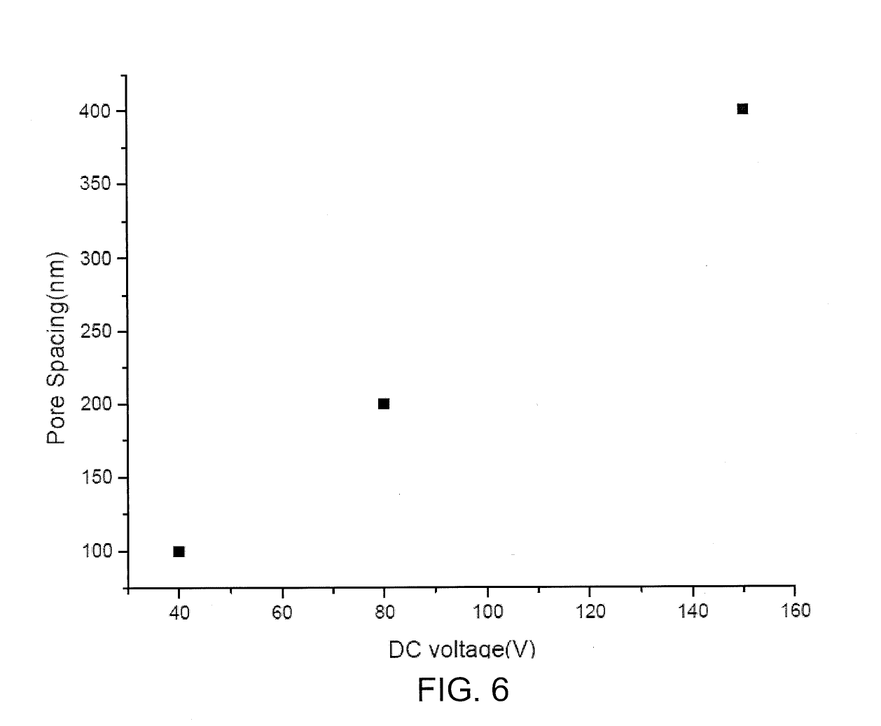

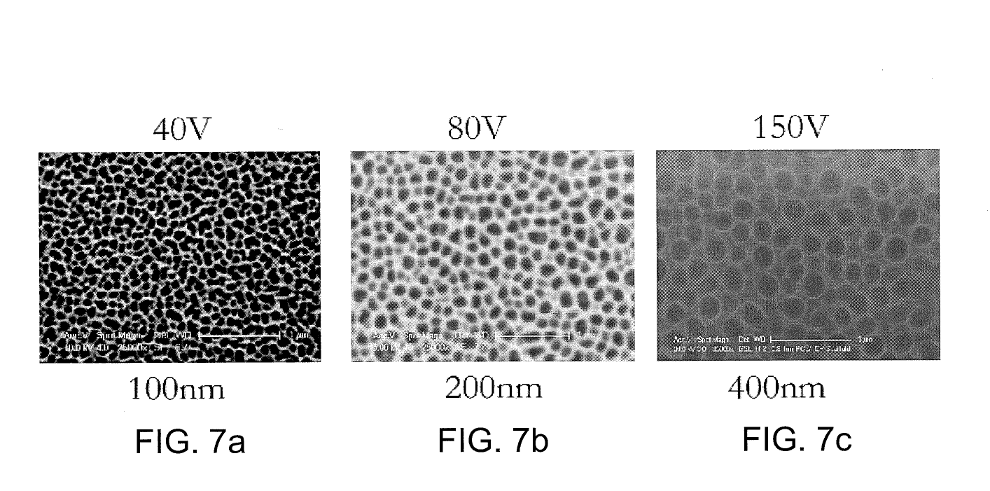

In embodiments of the present invention, the process parameters may be varied so that a porous aluminum oxide layer is formed having the desired properties, e.g., pore size, pore spacing, aluminum oxide layer thickness, etc. The process parameters may include electrolyte composition and concentration, temperature of the electrolyte bath, the voltage used for the anodization process, and the anodization time. For example, the acidic electrolyte used may be phosphoric acid, sulfuric acid, and/or citric acid with an appropriate concentration, e.g., 4 wt % concentration phosphoric acid. The electrolyte bath temperature may be maintained from about 0 to about 25° C., and preferably from about 0 to about 10° C. The thickness of the porous aluminum oxide layer may be varied depending on the anodization time. For example, as shown in FIGS. 4 and 5, the film growth may be relatively linear under certain conditions with a film thickness ranging from 0 to about 1400 nm or larger, and preferably about 200 nm for some applications. In addition, the pore spacing may be varied depending on the voltage used. For example, as shown in FIGS. 6 and 7, the spacing of the pores from the center of one pore to the center of an adjacent pore may be increased with increasing voltage. In embodiments of the present invention, the voltage used may range from about 0 to about 1000V, and preferably from about 40V to about 200V.

Returning to the process of FIG. 1, the width of the pores may optionally be widened to a desired size in step 120. This may be accomplished by subjecting the porous aluminum oxide layer to an etching process after anodization. For example, after removing the voltage, the porous aluminum oxide layer may be left in the acidic electrolyte solution to allow the pore size to widen and to remove the non-porous barrier layer adjacent to the substrate. This occurs because the etching solution contacts the cell wall along the length of the pore and at the bottom of the pore, removing material in these areas. After a sufficient time, the non-porous barrier layer will be completely removed at the bottom of each of the pores, providing an aluminum oxide layer that has openings that proceed through the films entire thickness to the substrate or any layer formed on the substrate.

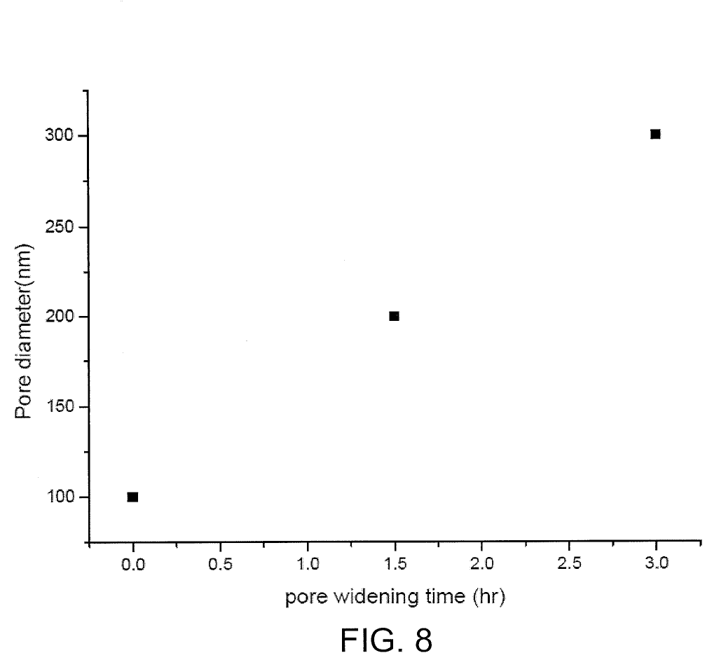

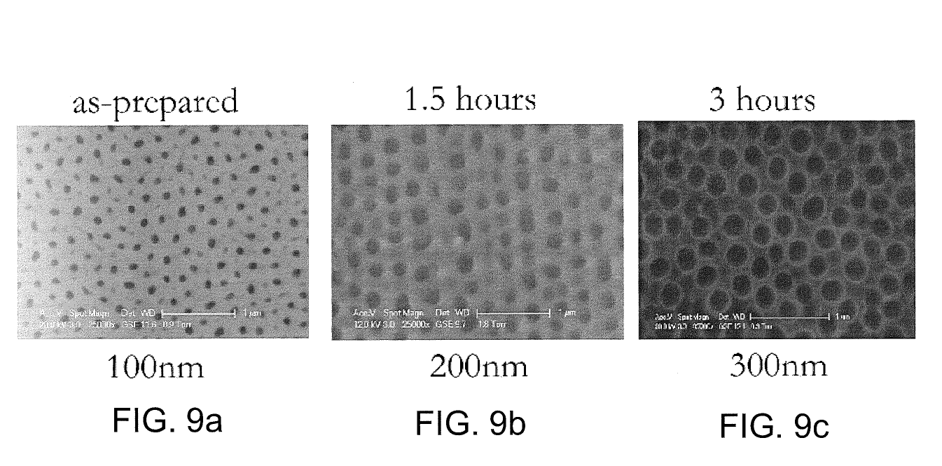

Alternatively, or additionally, the anodized sample may be subjected to another etching solution, such as an acidic solution having a different concentration and/or a different composition than the acidic electrolyte solution used for the anodization process. For example, the sample may be anodized in 4 wt % phosphoric acid and the anodized sample may be placed in 5 wt % phosphoric acid. The pore diameter may be varied depending on the time spent in the etchant. For example, as shown in FIGS. 8 and 9, the pore diameter may be widened the longer the anodized sample is left in the acidic electrolyte solution. In embodiments of the present invention, the pore widening time used may range from about 0 to about 3 hours. Thus, the thickness, the pore spacing, and the pore diameter of the porous aluminum oxide layer may be selected based on the desired application for the porous aluminum oxide layer.

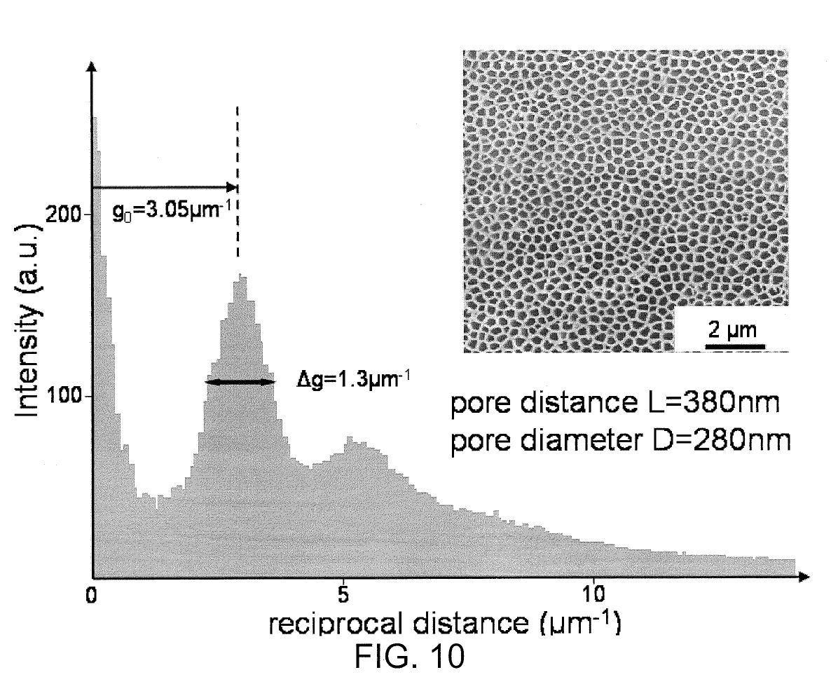

The process produces a porous aluminum oxide layer adjacent to the substrate having a hexagonal cell structure with, preferably, some degree of randomness in the pore distribution, such as shown in FIG. 10. However, by tailoring the process parameters, a hexagonal cell structure with minimal defects may also be formed having a limited degree of randomness. In this case, the porous aluminum oxide layer may form a more conventional periodic grating, having relative regularity in pore opening size and spacing between openings. FIG. 10 shows a SEM micrograph of a porous alumina structure formed according to embodiments of the present invention after a pore widening treatment and the resulting 2D fast Fourier transformation (FFT) of the SEM image. As shown in FIG. 10, the regularity of the pore distribution may be calculated by the FFT of the SEM image, which is similar to the diffraction pattern of a polycrystalline material. To derive the characteristic length scale of the porous aluminum oxide layer, the averaged radial intensity distribution is plotted as a function of distance from the center. From the scattering peak at the characteristic spatial frequency of g₀=3.05 μm⁻¹, the average interpore distance of the porous aluminum oxide structure may be determined to be

$$L = \frac{2}{\sqrt{3}} \cdot \frac{1}{{g}_{0}} \qquad ( 1 )$$

which is about 380 nm. This calculated result also agrees with literature which showed that the interpore distance of the porous aluminum oxide layer is linearly proportional to the applied anodization voltage:

L=2.5V=2.5*150=375 nm (2)

As shown, the distribution of the interpore distance may be determined to be Δg=1.3 μm⁻¹ by measuring the full width at half maximum (FWHM) of the peak. Therefore, the average spacing between pores may be about 380 nm with a range of about 310-480 nm at the FWHM. The average pore diameter was determined to be about 280 nm from the SEM image. This pseudo-periodic structure with some limited degree of randomness in the pore distribution differs from a random pattern in a surface or structure which would show a very broad, very shallow distribution with no peaks substantially discernable in the graph.

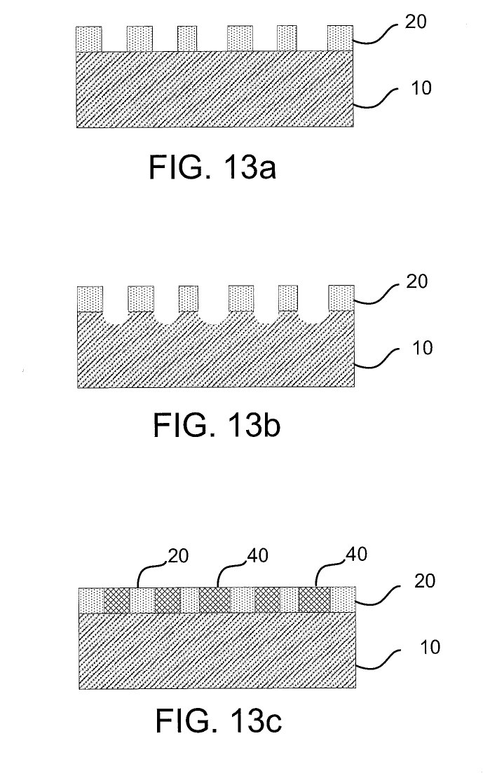

The resulting porous aluminum oxide layer may be used as a pseudo-periodic grating within a photovoltaic cell. Alternatively, the porous aluminum oxide layer may be used as a sacrificial layer for patterning subsequent layers and/or the substrate in the photovoltaic cell as will be discussed in more detail below with respect to FIGS. 13a-13c.

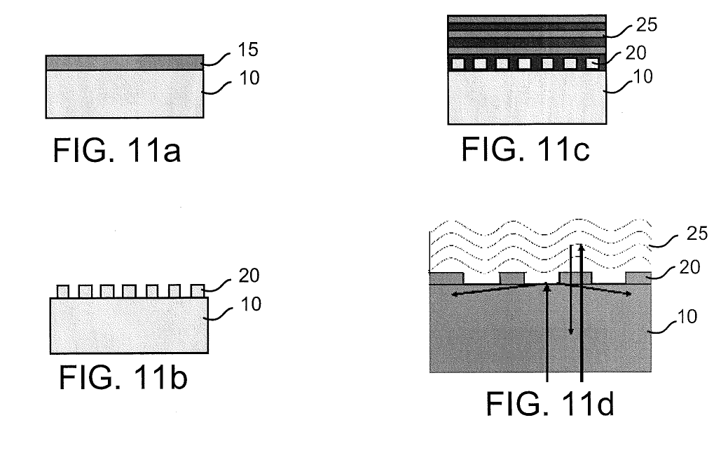

FIGS. 11a-11c show a process of manufacturing a photovoltaic cell according to embodiments of the present invention. In FIGS. 11a and 11b, the aluminum layer 15 is formed adjacent to the substrate 10 and then the aluminum 15 is anodized to produce a porous aluminum oxide layer 20 formed on the substrate 10 as described above. In FIG. 11c, a reflector 25 is formed adjacent to the porous aluminum oxide layer 20 by any known method. For example, the reflector may be one or more suitable metal layers, and preferably a distributed Bragg reflector (DBR). An exemplary DBR structure that may be formed is described in Zeng et al. “New Solar Cells with Novel Light Trapping via Textured Photonic Crystal Back Reflector,” Mater. Res. Soc. Symp. Proc., vol. 891 (2006), which is incorporated by reference herein in its entirety. During the deposition process, the pores of the aluminum oxide layer 20 are filled in with the one or more reflector layers 25. For example, a silicon layer may be formed on the porous aluminum oxide layer by plasma enhanced chemical vapor deposition (PECVD), filling in the pores. A DBR 25 having alternating layers of Si and SiO₂, e.g., four or five pairs of layers, may be formed adjacent to the porous aluminum oxide layer 20 by PECVD. The DBR is a multilayer stack which forms a one-dimensional photonic crystal with nearly 100% reflectivity in the red and near infrared range. As shown schematically in FIG. 11d, the pseudo-periodic grating 20 may diffract the incident light (shown as dark arrows coming from the bottom of the substrate 10) into oblique angles, thus total internal reflection may occur at the front surface of the silicon if the diffractive angle is larger than the critical angle between the silicon and air interface. It was determined that the pseudo-periodic grating 20 provides even better light trapping effects than perfectly periodic gratings. For example, Table 1 shows the simulated short-circuit current density of solar cells with different backside structures and enhancement factor. In these simulation studies, the pseudo-periodic grating (shown as DQPS in Table 1) provides 53% absorption enhancement under AM1.5G illumination, indicating a 53% enhancement of cell efficiency, which is even greater than the 49% enhancement obtained from a perfectly periodic grating (shown as TPC in Table 1).

TABLE 1

| | | Relative |
|---|---|---|
| | J_{sc} (mA/cm²) | enhancement |
| Bare 2 μm Si | 12.3 | / |
| TPC | 18.3 | 49% |
| DQPS | 18.8 | 53% |

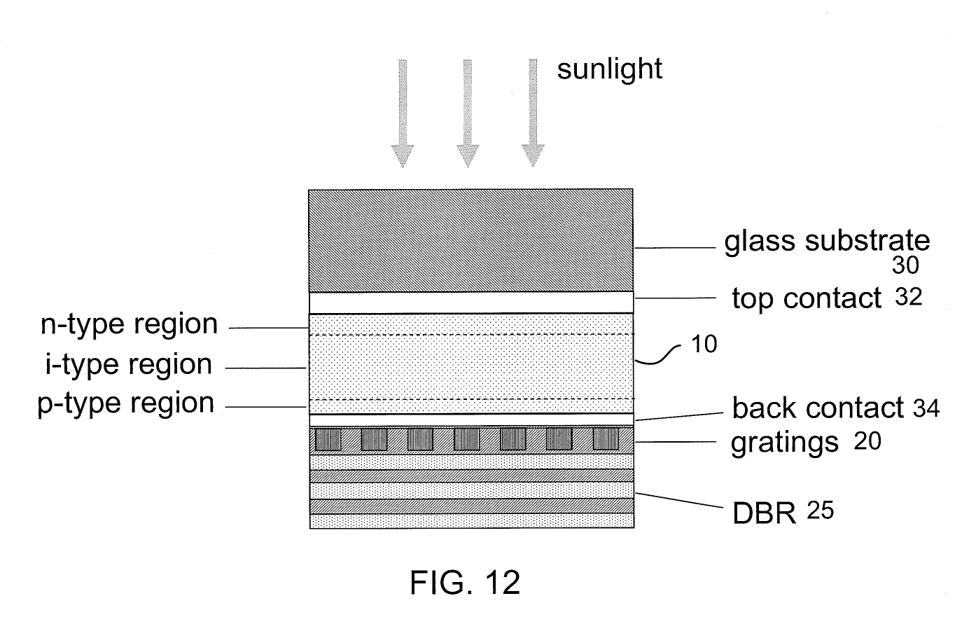

FIG. 12 shows an exemplary photovoltaic cell that may be formed with the pseudo-periodic grating 20 according to embodiments of the present invention. As shown, the photovoltaic cell may have a glass substrate or plastic cover or other encapsulant 30 and a top contact 32 formed adjacent to the front side (the side facing the incoming light) of the substrate 10. The top contact 32 collects the current generated by the photovoltaic cell and is usually made of a good conductor, such as a metal. An optional antireflective coating (not shown) may also be formed adjacent to the front side of the substrate 10 between the top contact 32 and the substrate 10 to help guide the light into the photovoltaic cell, since otherwise much of the light may bounce off the surface of the photovoltaic cell. As mentioned previously, the substrate 10 includes an active absorption layer, such as an n-type region, an i-type region, and a p-type region. The back side of the substrate 10 may include a back contact 34, which acts as a conductor and covers the back surface of the active absorption layer 10. The pseudo-periodic grating 20 is formed adjacent to the back contact 34, and the reflector 25, such as a DBR, is formed adjacent to the pseudo-periodic grating 20. Other layers may also be used in addition to these various layers on or between the layers as known by those skilled in the art.

FIGS. 13a-13c show a process of using the porous aluminum oxide layer as a sacrificial layer for patterning subsequent layers and/or the substrate in the photovoltaic cell. As shown in FIG. 13a, the porous aluminum oxide layer 20 is formed adjacent to the substrate 10 as described above. In FIG. 13b, the porous aluminum oxide layer 20 may be used as a patterning layer or etching mask so that areas of the substrate 10 immediately adjacent to the porous aluminum oxide layer 20 are protected from any subsequent etching or removal process. The etching process may include known wet etching or dry etching processes. For example, the sample may be exposed to a suitable etching solution that preferentially etches the exposed substrate material 10 at the bottom of each opening. Alternatively, the sample may be subjected to dry etching process, such as reactive ion etching or sputter etching process. In this embodiment, the pseudo-periodic pattern of the porous aluminum oxide layer 20 is transferred to the upper region of the active absorption layer 10. The porous aluminum oxide layer 20 may then be removed (not shown) and a reflector 25 may be formed adjacent to the active absorption layer 10 as described previously with respect to FIG. 11c. Thus, a region of the active absorption layer 10 forms the pseudo-periodic grating for the photovoltaic cell.

Alternatively, or additionally, a grating layer 40 may be formed within the openings in the porous aluminum oxide layer 20, such as shown in FIG. 13c. The grating layer 40 may be formed of silicon, a conductive oxide layer, such as an indium tin oxide material, and/or materials with high refractive indices, e.g., refractive indices greater than about 2.0. In this embodiment, an inverse impression of the pseudo-periodic pattern of the porous aluminum oxide layer 20 is transferred to the grating layer 40. The porous aluminum oxide layer 20 may then be removed (not shown) and a reflector 25 may be formed, as described previously with respect to FIG. 11c, adjacent to the grating layer 40 and the exposed active absorption layer 10. Thus, the grating layer 40 forms the pseudo-periodic grating for the photovoltaic cell.

One or more additional porous aluminum oxide layers 20 may be formed as described above adjacent to or in the substrate 10, the reflector 25, and/or the grating layer 40. The one or more additional porous aluminum oxide layers 20 may be used within the photovoltaic cell as an additional pseudo-periodic grating or a sacrificial layer for forming additional pseudo-periodic gratings as described above.

As known by those skilled in the art, one or more photovoltaic cells may be connected together to form larger units called modules, and modules may be connected together to form even larger units called arrays, which may be interconnected together, etc. Thus, embodiments of the present invention may include a photovoltaic system having a plurality of photovoltaic cells coupled to one another.

Although the above discussion discloses various exemplary embodiments of the invention, it should be apparent that those skilled in the art can make various modifications that will achieve some of the advantages of the invention without departing from the true scope of the invention.

What is claimed is:

1. A method of manufacturing a photovoltaic cell, the method comprising:
providing an active absorption layer;
forming a pseudo-periodic grating adjacent to the active absorption layer; and
forming a reflector adjacent to the pseudo-periodic grating.

2. The method of claim 1, wherein the reflector is a distributed Bragg reflector.

3. The method of claim 1, wherein forming the pseudo-periodic grating includes forming an aluminum layer adjacent to the absorption layer, and anodizing the aluminum layer in the presence of an acid to establish a pseudo-periodic structure of aluminum oxide.

4. The method of claim 3, wherein forming the pseudo-periodic grating further includes forming a grating layer using the pseudo-periodic structure as a template and then removing the pseudo-periodic structure, so that the grating layer forms the pseudo-periodic grating.

5. The method of claim 4, wherein the grating layer is made of a transparent conductive oxide material or silicon.

6. The method of claim 4, wherein the grating layer is made of a material with a high refractive index.

7. The method of claim 3, wherein forming the pseudo-periodic grating further includes removing at least some portion of the active absorption layer in pore areas of the pseudo-periodic structure and then removing the pseudo-periodic structure so that a region of the active absorption layer forms the pseudo-periodic grating.

8. A device having a photovoltaic cell produced according to the method of claim 1.

9. A photovoltaic cell comprising:
an active absorption layer;
a pseudo-periodic grating adjacent to the active absorption layer; and
a reflector adjacent to the pseudo-periodic grating.

10. The photovoltaic cell of claim 8, wherein the reflector is a distributed Bragg reflector.

11. The photovoltaic cell of claim 8, wherein the pseudo-periodic grating is made of aluminum oxide.

12. The photovoltaic cell of claim 8, wherein the pseudo-periodic grating is made of a transparent conductive oxide material or silicon.

13. The photovoltaic cell of claim 8, wherein the pseudo-periodic grating is made of a material with a high refractive index.

14. A method of manufacturing a photovoltaic cell, the method comprising:
providing an active absorption layer;
forming an aluminum layer adjacent to the absorption layer;
anodizing the aluminum layer in the presence of an acid to form a porous aluminum oxide layer; and
forming a reflector adjacent to the porous aluminum oxide layer.

15. The method of claim 14, wherein the reflector is a distributed Bragg reflector.

16. The method of claim 14, further comprising forming a grating layer using the porous aluminum oxide layer as a template and then removing the porous aluminum oxide layer.

17. The method of claim 16, wherein the grating layer is made of a transparent conductive oxide material or silicon.

18. The method of claim 16, wherein the grating layer is made of a material with a high refractive index.

19. The method of claim 14, further comprising removing at least some portion of the active absorption layer in pore areas of the porous aluminum oxide layer and then removing the porous aluminum oxide layer.

20. A device having a photovoltaic cell produced according to the method of claim 1.
